(19) United States
(12) Patent Application Publication
(10) Pub. No.: US 2019/0203983 A1
(43) Pub. Date: Jul. 4, 2019

(54) COOLING APPARATUS USING THERMOELECTRIC MODULES

(71) Applicant: LG ELECTRONICS INC., Seoul (KR)

(72) Inventors: Yongseog JEON, Seoul (KR); Joongnyon KIM, Seoul (KR); Hyeuk CHANG, Seoul (KR)

(73) Assignee: LG ELECTRONICS INC., Seoul (KR)

(21) Appl. No.: 15/941,330

(22) Filed: Mar. 30, 2018

(30) Foreign Application Priority Data
Jan. 2, 2018 (KR) 10-2018-0000227

(51) Int. Cl. F25B 21/04; F28D 15/04; H05K 7/20

(52) U.S. Cl. CPC F25B 21/04; F28D 15/043; H05K 7/20336; H01L 35/28; H05K 7/20318; H05K 7/20327; F25B 2321/0252; H05K 7/20309

(57) ABSTRACT

Disclosed is a cooling apparatus using thermoelectric modules. The cooling apparatus includes a cooling container, a first thermoelectric module contacting the cooling container at a first position, and a first heat dissipating module contacting the first thermoelectric module. The first heat dissipating module includes a loop heat pipe including a first evaporation unit contacting the first thermoelectric module and provided with a wick structure located therein, a first condensation unit located at the outside of the cooling container, a first vapor pipe line configured to interconnect one side of the first evaporation unit and one side of the first condensation unit such that gas is placed therein, and a first liquid pipe line configured to interconnect the other side of the first evaporation unit and the other side of the first condensation unit such that a working fluid is placed therein.

This application claims the benefit of Korean Patent Application No. 10-2018-0000227 filed on Jan. 2, 2018, which is hereby incorporated by reference as if fully set forth herein.

### BACKGROUND OF THE INVENTION

### Field of the Invention

The present invention relates to a cooling apparatus, and more particularly, to a cooling apparatus using thermoelectric modules.

### Discussion of the Related Art

In general, a compression cooling method, in which cooling is executed by circulating a refrigerant through a compressor, an evaporator, a condenser, etc., is used as a cooling method of cooling apparatuses, such as a water purifier, a water cooler and a refrigerator.

In addition, a cooling method using a thermoelectric semiconductor is used. Such a thermoelectric semiconductor is a device which cools a target object using the thermoelectric effect.

The thermoelectric effect means reversible and direct energy conversion between heat and electricity. The thermoelectric effect is generated by movement of charge carriers, i.e., electrons and holes, within a material.

The Seebeck effect means direct conversion of a temperature difference into electricity and is applied to power generation using electromotive force caused by a temperature difference between both ends of a thermoelectric material. The Peltier effect means generation of heat at an upper junction and absorption of heat at a lower junction, when current flows through a circuit, and is applied to cooling fields using a temperature difference between both ends caused by current applied from the outside. The Seebeck effect and the Peltier effect are thermodynamically reversible and thus differ from the Joule heating which is thermodynamically irreversible.

At present, thermoelectric materials are applied as active cooling systems of semiconductor equipment and other electronic equipment, which are difficult to solve generation of heat using passive cooling systems, and demand for thermoelectric materials has been expanded in fields in which a generation of heat cannot be solve using conventional systems employing a refrigerant gas compression method, such as a precise temperature control system applied to DNA studies.

A cooling method using a thermoelectric material is non-vibration and low-noise eco-friendly technology in which a refrigerant gas causing environmental problems is not used. Application of such a cooling method may be expanded to a wide range of general-purpose cooling fields of refrigerators, air conditioners, etc., for domestic and commercial use.

A cooling effect using a thermoelectric material is restrictive up to now. That is, as a side part or a bottom part of a cooling container is cooled using a thermoelectric semiconductor, convection of heat is restrictively carried out and, thus, only a partial cooling effect may be acquired.

Therefore, improvement of the cooling effect effectively using performance of such a thermoelectric material has been required.

A thermoelectric module (thermoelectric element) utilizes the thermoelectric material. When the thermoelectric module operates, a surface thereof is cooled and an opposite surface is heated, thereby maintaining a predetermined temperature difference at the opposite surfaces.

That is, the thermoelectric module may reduce temperature of an object using the cooled surface, and raise temperature of an object using the heated surface.

When reducing temperature of an object using the cooled surface, it is required to cool the opposite heated surface intentionally, so as to maintain the reduced temperature.

### SUMMARY OF THE INVENTION

Accordingly, the present invention is directed to a cooling apparatus using a thermoelectric module that substantially obviates one or more problems due to limitations and disadvantages of the related art.

An object of the present invention is to provide a cooling apparatus using a thermoelectric module in which a heat dissipating module uses a loop heat pipe structure.

Another object of the present invention is to provide a cooling apparatus using a thermoelectric module in which a loop heat pipe structure is applied to a heat dissipating module related to at least the thermoelectric module which is intermittently operated according to the temperature of a cooling container.

Yet another object of the present invention is to provide a cooling apparatus using a thermoelectric module in which a loop heat pipe structure is applied to a heat dissipating module connected to the thermoelectric module, operation of which is stopped in a cold reserving section in a water purifier, as one example.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a cooling apparatus using thermoelectric modules, including a cooling container, a first thermoelectric module contacting the cooling container at a first position, and a first heat dissipating module installed so as to contact the first thermoelectric module, wherein the first heat dissipating module includes a loop heat pipe including a first evaporation unit contacting the first thermoelectric module and provided with a wick structure located therein, a first condensation unit located at the outside of the cooling container, a first vapor pipe line configured to interconnect one side of the first evaporation unit and one side of the first condensation unit and gas is placed in the first vapor pipe line, and a first liquid pipe line configured to interconnect the other side of the first evaporation unit and the other side of the first condensation unit and a working fluid is placed in the first liquid pipe line.

The cooling apparatus may further include a second thermoelectric module contacting the cooling container at a second position, and a second heat dissipating module installed so as to contact the second thermoelectric module.

The second heat dissipating module may include a heat pipe including a pipe unit forming one closed space in which the working fluid is placed, and a wick structure located at the entirety of the inside of the pipe unit.

The second heat dissipating module may include a loop heat pipe including a second evaporation unit contacting the second thermoelectric module and provided with a wick structure located therein, a second condensation unit located at the outside of the cooling container, a second vapor pipe line configured to interconnect one side of the second evaporation unit and one side of the second condensation unit and the gas is placed in the second vapor pipe line, and a second liquid pipe line configured to interconnect the other side of the second evaporation unit and the other side of the second condensation unit and the working fluid is placed in the second liquid pipe line.

The second heat dissipating module may include a second evaporation unit contacting the second thermoelectric module and provided with a wick structure located therein, and the first evaporation unit and the second evaporation unit may be connected in parallel to the first vapor pipe line and the first liquid pipe line.

The first evaporation unit and the second evaporation unit may be connected in parallel to the first vapor pipe line and the first liquid pipe line through a vapor sub-pipe line and a liquid sub-pipe line.

At least one of the first condensation unit or the second condensation unit may have a structure which is continuously bent within a designated area.

The first thermoelectric module may be a thermoelectric module which is intermittently operated according to the temperature of the cooling container, and the second thermoelectric module may be a thermoelectric module which is continuously operated.

In another aspect of the present invention, a cooling apparatus using thermoelectric modules, including a cooling container, a first thermoelectric module contacting the cooling container at a first position, a first heat dissipating module installed so as to contact the first thermoelectric module and having a loop heat pipe structure, a second thermoelectric module contacting the cooling container at a second position, and a second heat dissipating module installed so as to contact the second thermoelectric module and having one of a loop heat pipe structure and a heat pipe structure.

The first heat dissipating module may include a loop heat pipe including a first evaporation unit contacting the first thermoelectric module and provided with a wick structure located therein, a first condensation unit located at the outside of the cooling container, a first vapor pipe line configured to interconnect one side of the first evaporation unit and one side of the first condensation unit and gas is placed in the first vapor pipe line, and a first liquid pipe line configured to interconnect the other side of the first evaporation unit and the other side of the first condensation unit and a working fluid is placed in the first liquid pipe line.

The second heat dissipating module may include a heat pipe including a pipe unit forming one closed space in which the working fluid is placed, and a wick structure located at the entirety of the inside of the pipe unit.

The second heat dissipating module may include a loop heat pipe including a second evaporation unit contacting the second thermoelectric module and provided with a wick structure located therein, a second condensation unit located at the outside of the cooling container, a second vapor pipe line configured to interconnect one side of the second evaporation unit and one side of the second condensation unit and the gas is placed in the second vapor pipe line, and a second liquid pipe line configured to interconnect the other side of the second evaporation unit and the other side of the second condensation unit and the working fluid is placed in the second liquid pipe line.

The second heat dissipating module may include a second evaporation unit contacting the second thermoelectric module and provided with a wick structure located therein, and the first evaporation unit and the second evaporation unit may be connected in parallel to the first vapor pipe line and the first liquid pipe line through a vapor sub-pipe line and a liquid sub-pipe line.

At least one of the first condensation unit or the second condensation unit may have a structure which is continuously bent within a designated area.

The first thermoelectric module may be a thermoelectric module which is intermittently operated according to the temperature of the cooling container, and the second thermoelectric module may be a thermoelectric module which is continuously operated.

In yet another aspect of the present invention, a cooling apparatus using thermoelectric modules, including a cooling container, and at least two thermoelectric modules installed on the cooling container, and heat dissipating modules installed so as to contact the at least two thermoelectric modules, wherein, among the heat dissipating modules, the first heat dissipating module installed on the thermoelectric module, which is intermittently operated according to the temperature of the cooling container, has a loop heat pipe structure, and the second heat dissipating module installed on the thermoelectric module, which is continuously operated, has one of a loop heat pipe structure and a heat pipe structure.

The heat dissipating module having the loop heat pipe structure may include an evaporation unit contacting the thermoelectric module and provided with a wick structure located therein, a condensation unit located at the outside of the cooling container, a vapor pipe line configured to interconnect one side of the evaporation unit and one side of the condensation unit such that gas is placed in the vapor pipe line, and a liquid pipe line configured to interconnect the other side of the evaporation unit and the other side of the condensation unit such that a working fluid is placed in the liquid pipe line.

The condensation unit may have a structure which is continuously bent within a designated area.

The heat dissipating module having the heat pipe structure may include a heat pipe including a pipe unit forming one closed space in which the working fluid is placed, and a wick structure located at the entirety of the inside of the pipe unit.

If the second heat dissipating module has the loop heat pipe structure, the first heat dissipating module and the second heat dissipating module may be connected in parallel.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a perspective view illustrating a cooling apparatus using thermoelectric modules in accordance with one embodiment of the present invention;

FIG. 2 is a perspective view illustrating a loop heat pipe structure in accordance with one embodiment of the present invention;

FIG. 3 is a schematic view illustrating an operating principle of the loop heat pipe structure in accordance with one embodiment of the present invention;

FIG. 4 is a perspective view illustrating a cooling apparatus using thermoelectric modules in accordance with another embodiment of the present invention;

FIG. 5 is a schematic view illustrating an operating principle of a heat pipe structure in accordance with one embodiment of the present invention;

FIG. 6 is a schematic view illustrating heat flow of a water purifier provided with a cooling apparatus using a heat pipe;

FIG. 7 is a perspective view illustrating a cooling apparatus using thermoelectric modules in accordance with another embodiment of the present invention;

FIG. 8 is a schematic view illustrating the cooling apparatus shown in FIG. 7;

FIG. 9 is a perspective view illustrating a cooling apparatus using thermoelectric modules in accordance with yet another embodiment of the present invention; and

FIG. 10 is a graph representing performance of a cooling apparatus using thermoelectric modules in accordance with the present invention.

### DETAILED DESCRIPTION OF THE INVENTION

Reference will now be made in detail to the preferred embodiments of the present invention, examples of which are illustrated in the accompanying drawings.

Hereinafter, specific embodiments of the present invention will be exemplarily illustrated in detail while permitting various alterations and modifications. Thus, it is intended that the present invention cover the modifications and variations of the invention within the scope of the appended claims and their equivalents.

In the following description of the embodiments, it will be understood that, when each element, such as a layer, region, or substrate, is referred to as being formed “on” or “under” another element, it can be directly “on” or “under” the other element or be indirectly formed with one or more intervening elements therebetween.

It will be understood that although the terms first, second, etc. may be used herein to describe various elements, components, regions, layers and/or regions, these elements, components, regions, layers and/or regions should not be limited by these terms. These terms are generally only used to distinguish one element from another.

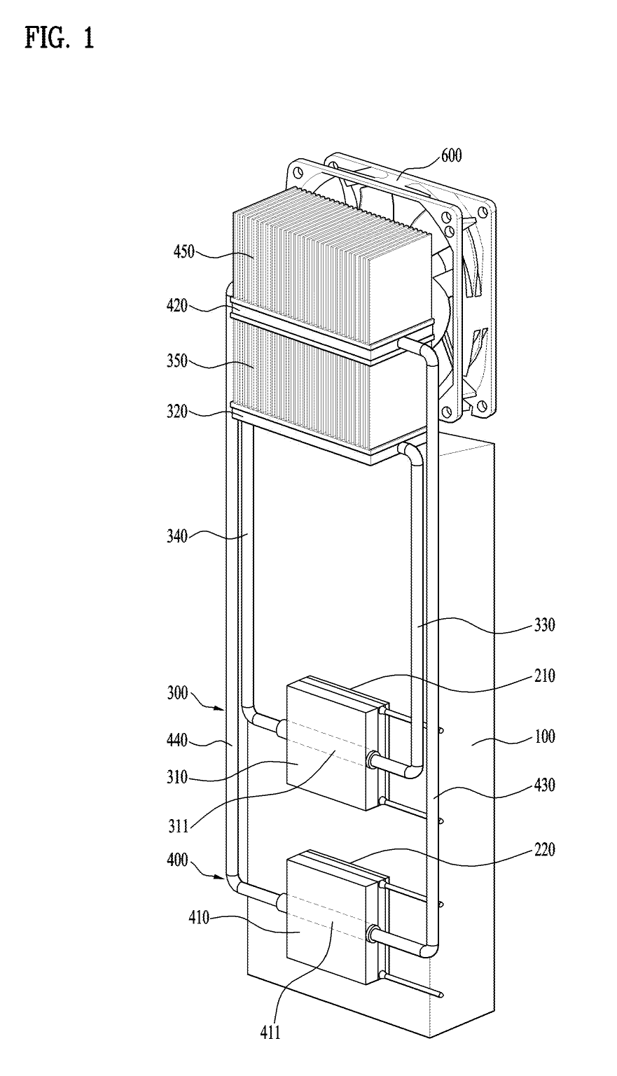

FIG. 1 is a perspective view illustrating a cooling apparatus using thermoelectric modules in accordance with one embodiment of the present invention.

With reference to FIG. 1, the cooling apparatus includes a cooling container 100, at least two thermoelectric modules 210 and 220 installed on the cooling container 100, and heat dissipating modules 300 and 400 installed so as to contact the thermoelectric modules 210 and 220.

The cooling container 100 may be a part of an apparatus using cooling action using the thermoelectric modules 210 and 220. For example, the cooling container 100 may be an inner space of an apparatus using cooling action, such as a water tank (a cold water tank) of a water purifier or a refrigerating chamber of a refrigerator. Such a refrigerator may include a portable refrigerator or a refrigerator for vehicles. However, the cooling container 100 is not limited to these apparatuses and may be applied to all apparatuses which use cooling action using the thermoelectric modules 210 and 220.

The thermoelectric modules (TEM) 210 and 220 include a thermoelectric material using the thermoelectric effect.

The thermoelectric effect means reversible and direct energy conversion between heat and electricity. The thermoelectric effect is generated by movement of charge carriers, i.e., electrons and holes, within a material. The thermoelectric modules 210 and 220 use the Seebeck effect and the Peltier effect.

The Seebeck effect means direct conversion of a temperature difference into electricity and is applied to power generation using electromotive force caused by a temperature difference between both ends of a thermoelectric material. The Peltier effect means generation of heat at an upper junction and absorption of heat at a lower junction, when current flows through a circuit, and is applied to cooling fields using a temperature difference between both ends caused by current applied from the outside. The Seebeck effect and the Peltier effect are thermodynamically reversible and thus differ from the Joule heating which is thermodynamically irreversible.

The heat dissipating modules 300 and 400 may be elements to transmit heat, generated together with cooling action of the thermoelectric modules 210 and 220, to the outside. The heat dissipating modules 300 and 400 may be respectively installed so as to contact the thermoelectric modules 210 and 220.

The heat dissipating modules 300 and 400 may have a heat pipe structure or a loop heat pipe structure. For example, one of the thermoelectric modules 210 and 220 may be intermittently operated, and the other of the thermoelectric modules 210 and 220 may be continuously operated. Here, the heat dissipating module (hereinafter referred to as a first heat dissipating module 300) installed on the thermoelectric module which is intermittently operated may have a loop heat pipe structure, and the heat dissipating module (hereinafter referred to as a second heat dissipating module 400) installed on the thermoelectric module which is continuously operated may have a loop heat pipe structure or a heat pipe structure. This will be described in more detail later.

FIG. 1 exemplarily illustrates the first heat dissipating module 300 and the second heat dissipating module 400, both of which have a loop heat pipe structure.

The first and second heat dissipating modules 300 and 400 having such a loop heat pipe structure may include evaporation units 310 and 410 contacting the thermoelectric modules 210 and 220 and provided with wick structures 311 and 411 located therein, condensation units 320 and 420 installed at the outside of the cooling container 100, vapor pipe lines 330 and 430, each of which interconnects one side of each of the evaporation units 310 and 410 and one side of each of the condensation units 320 and 420 such that gas is placed therein, and liquid pipe lines 340 and 440, each of which interconnects the other side of each of the evaporation units 310 and 410 and the other side of each of the condensation units 320 and 420 such that a working fluid is placed therein.

Further, heat sinks 350 and 450 may contact the condensation units 320 and 420. A heat dissipation fan 600 may be installed on the heat sinks 350 and 450.

The wick structures 311 and 411 may be formed as a groove type, a mesh type, a sintering type, etc. according to materials thereof, and heat transfer performance of the wick structures 311 and 411 may differ according to installed directions of the wick structures 311 and 411 due to these materials thereof.

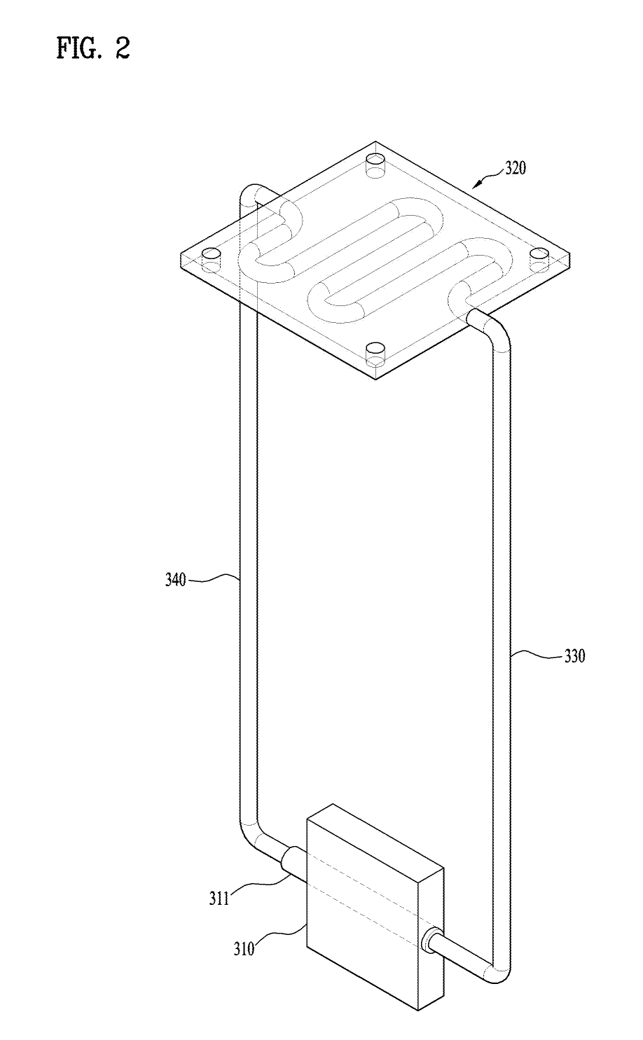

FIG. 2 is a perspective view illustrating a loop heat pipe structure in accordance with one embodiment of the present invention.

FIG. 2 illustrates the loop heat pipe structure of the first heat dissipating module 300. With reference to FIG. 2, the loop heat pipe structure may have, as described above, the evaporation unit 310 contacting the thermoelectric module 210 and provided with the wick structure 311 located therein, the condensation unit 320 installed at the outside of the cooling container 100, the vapor pipe line 330 interconnecting one side of the evaporation unit 310 and one side of the condensation unit 320 such that the gas is placed therein, and the liquid pipe line 340 interconnecting the other side of the evaporation unit 310 and the other side of the condensation unit 320 such that the working fluid is placed therein.

Further, as exemplarily shown in this figure, the condensation unit 320 may have a pipe structure 321 which is continuously bent within a designated area. That is, the condensation unit 320 may have a shape which is bent several times or be formed as a separate block so as to increase a surface area of the condensation unit 320.

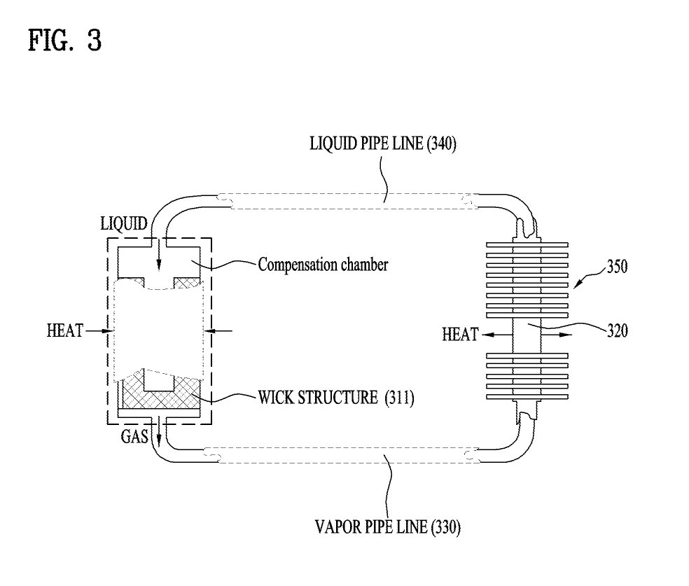

FIG. 3 is a schematic view illustrating an operating principle of the loop heat pipe structure in accordance with one embodiment of the present invention.

Such a loop heat pipe includes the vapor pipe line 330 and the liquid pipe line 340 which interconnect the evaporation unit 310 and the condensation unit 320 to each other.

The evaporation unit 310 forms a compensation chamber and includes the wick structure 311 located therein. As such, the loop heat pipe includes the wick structure 311 located only in the evaporation unit 310.

Further, the heat sink 350 may be installed on the condensation unit 320.

As such, the loop heat pipe includes the vapor pipe line 330 and the liquid pipe line 340 and, thus, a vaporized fluid passes through the vapor pipe line 330 and a liquefied fluid passes through the liquid pipe line 340.

The vapor pipe line 330 and the liquid pipe line 340 may be formed as a straight shape, or some sections of the vapor pipe line 330 and the liquid pipe line 340 may be bent as an arbitrary shape.

Heat is introduced into the evaporation unit 310 and thus the working fluid in the evaporation unit 310 is changed from a liquid phase to a vapor phase. The evaporation unit 310 may absorb a large amount of heat from the outside. Further, the evaporation unit 310 includes the wick structure 311 located therein, as described above, and the compensation chamber (i.e., a reservoir) is provided at one end of the evaporation unit 310. The liquefied working fluid is always stored in such a compensation chamber.

By such a process, the vapor pipe line 330 serves as a transfer path of the working fluid vaporized by the evaporation unit 310. (The vaporized working fluid flows from the evaporation unit 310 to the condensation unit 320.)

The condensation unit 320 liquefies the vaporized working fluid through a heat exchanger including the heat sink 350 and the heat dissipation fan 600. That is, the condensation unit 320 dissipates heat through the heat sink 350 and the heat dissipation fan 600, and phase transition of the working fluid from the gaseous state to the liquid state occurs.

Then, the liquefied working fluid passes through the liquid pipe line 340. That is, the liquid pipe line 340 serves as a transfer path of the liquefied working fluid. (The liquefied working fluid flows from the condensation unit 320 to the evaporation unit 310.)

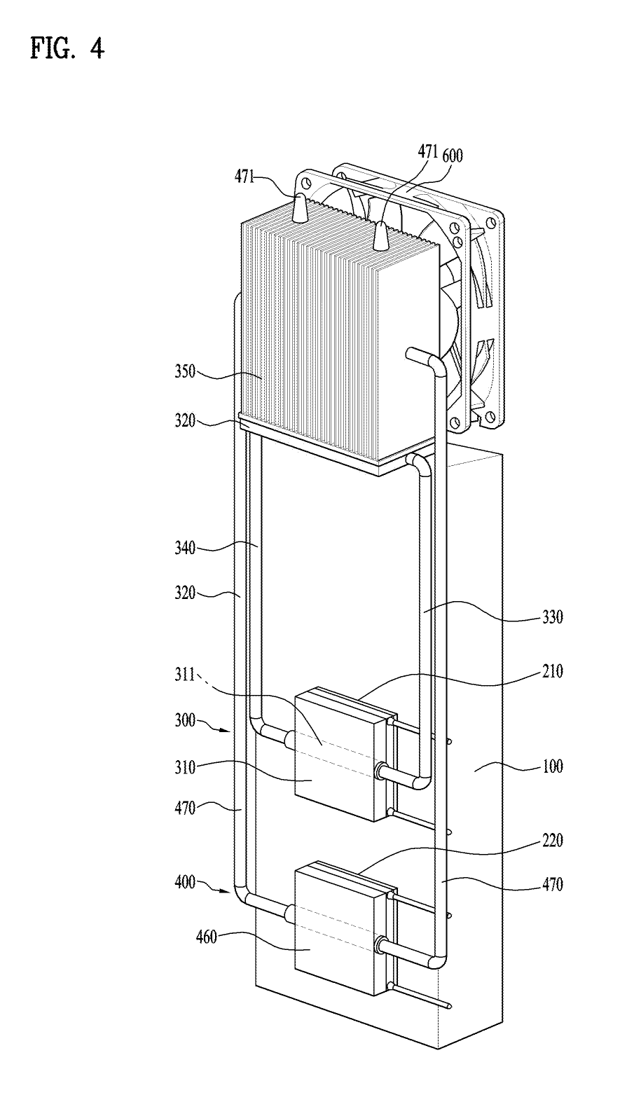

FIG. 4 is a perspective view illustrating a cooling apparatus using thermoelectric modules in accordance with another embodiment of the present invention.

With reference to FIG. 4, the cooling apparatus includes a cooling container 100, at least two thermoelectric modules 210 and 220 installed on the cooling container 100, and heat dissipating modules 300 and 400 installed so as to contact the thermoelectric modules 210 and 220.

Here, the cooling container 100 may be a part of an apparatus using cooling action using the thermoelectric modules 210 and 220. For example, the cooling container 100 may be an inner space of an apparatus using cooling action, such as a water tank (a cold water tank) of a water purifier or a refrigerating chamber of a refrigerator. Such a refrigerator may include a portable refrigerator or a refrigerator for vehicles. However, the cooling container 100 is not limited to these apparatuses and may be applied to all apparatuses which use cooling action using the thermoelectric modules 210 and 220.

The thermoelectric modules (TEM) 210 and 220 include a thermoelectric material using the thermoelectric effect.

The heat dissipating modules 300 and 400 may be elements to transmit heat, generated together with cooling action of the thermoelectric modules 210 and 220, to the outside. The heat dissipating modules 300 and 400 may be respectively installed so as to contact the thermoelectric modules 210 and 220.

The heat dissipating modules 300 and 400 may have a heat pipe structure or a loop heat pipe structure. For example, one of the thermoelectric modules 210 and 220 may be intermittently operated, and the other of the thermoelectric modules 210 and 220 may be continuously operated. Here, the heat dissipating module (hereinafter referred to as a first heat dissipating module 300) installed on the thermoelectric module which is intermittently operated may have a loop heat pipe structure, and the heat dissipating module (hereinafter referred to as a second heat dissipating module 400) installed on the thermoelectric module which is continuously operated may have a loop heat pipe structure or a heat pipe structure.

FIG. 4 exemplarily illustrates the first heat dissipating module 300 having a loop heat pipe structure and the second heat dissipating module 400 having a heat pipe structure.

The first heat dissipating module 300 having a loop heat pipe structure has the above-described configuration and a detailed description thereof will thus be omitted.

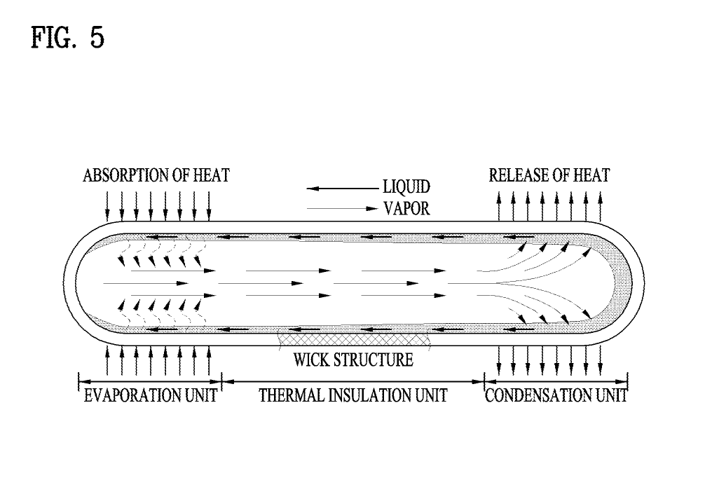

The second heat dissipating module 400 having a heat pipe structure may include a pipe unit 470 forming one closed space in which a working fluid is placed, and a wick structure located in the entirety of the inside of the pipe unit 470 (with reference to FIG. 5).

Inlets 471 through which the working fluid is injected into the pipe unit 470 may be provided at one end of the pipe unit 470.

FIG. 5 is a schematic view illustrating an operating principle of a heat pipe structure in accordance with one embodiment of the present invention.

As shown in this figure, the heat pipe structure includes a pipe unit forming one closed space in which a working fluid is placed, and a wick structure located in the entirety of the inside of the pipe unit.

That is, one end of the heat pipe structure constitutes an evaporation unit and the other end of the heat pipe structure constitutes a condensation unit.

The working fluid in the condensation unit, liquefied by releasing heat, flows from the condensation unit to the evaporation unit along the inner surface of the pipe unit. Thereafter, the evaporation unit absorbs heat from the working fluid and, thus, the working fluid in the evaporation unit is converted into a gaseous state and the working fluid in the gaseous state flows to the condensation unit along the wick structure within the pipe unit.

Heat exchange between the evaporation unit and the condensation unit is carried out by such a flow of the working fluid.

Here, with reference to FIGS. 1 to 5, the above-described operation of the cooling apparatus will be described in detail.

One embodiment of the present invention exemplarily describes a cooling apparatus applied to a cold water tank of a water purifier. That is, a cold water tank of a water purifier will be exemplarily described as the cooling container 100.

Table 1 below states an operating condition to make cold water in the water purifier. That is, if a cooling switch is primarily turned on or in a rapid cooling section, both the first thermoelectric module (TEM1) 210 and the second thermoelectric module (TEM2) 220 may be operated (ON).

Thereafter, when the cold water tank reaches a designated temperature and thus the cooling apparatus enters a cold reserving section, operation of the first thermoelectric module (TEM1) 210 is stopped (OFF) and the second thermoelectric module (TEM2) 220 alone may be operated (ON).

TABLE 1

| | TEM1 | TEM2 |
|---|---|---|
| Rapid cooling | On | On |
| Cold reserving | Off | On |

Here, the first thermoelectric module 210 and the second thermoelectric module 220 are not limited to the positions of FIGS. 1 and 4. That is, in FIGS. 1 and 4, the first thermoelectric module 210 may be placed under the second thermoelectric module 220.

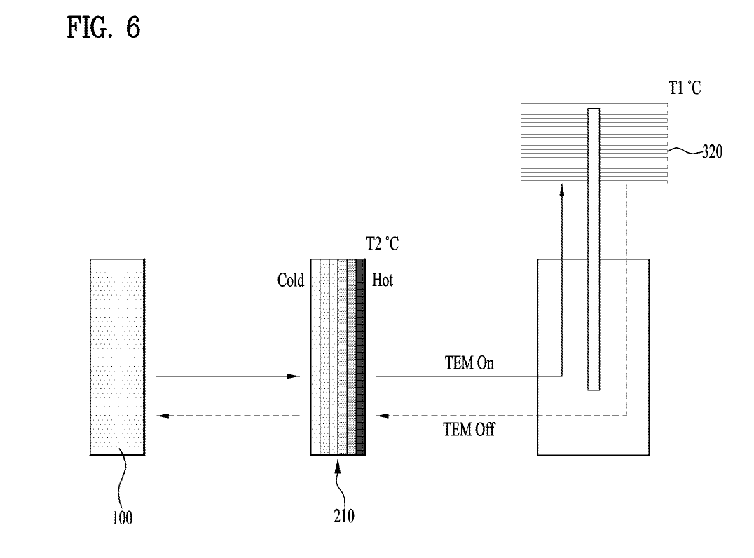

As such, the first thermoelectric module 210 may be intermittently operated according to the temperature of the cooling container 100. If the heat pipe structure is applied to the first thermoelectric module 210 which is intermittently operated, outdoor air may be introduced into the cooling container 100. Such a case will be described with reference to FIG. 6.

FIG. 6 is a schematic view illustrating heat flow of a water purifier provided with a cooling apparatus using a heat pipe.

With reference to FIG. 6, a thermoelectric module (TEM) 210 is placed on a cooling container 100, and a heat dissipating module 10 using a heat pipe structure is installed on the thermoelectric module (TEM) 210. Further, the heat dissipating module 10 is thermally coupled with a heat sink 20.

In this case, when the thermoelectric module (TEM) 210 is operated (TEM On), a cold part is formed at a part of the thermoelectric module (TEM) 210 contacting the cooling container 100 and a hot part is formed at the opposite part of the thermoelectric module (TEM) 210. Therefore, a temperature T2 (° C.) of an evaporation unit of the heat dissipating module 10 is higher than a temperature T1 (° C.) of a condensation unit of the heat dissipating module 10.

Therefore, as exemplarily shown by arrows displayed as a solid line in FIG. 6, heat of the hot part is transmitted to the heat sink 20 through the heat dissipating module 10 using the heat pipe structure, and the heat transmitted to the heat sink 20 is cooled by cooling fins provided on the heat sink 20. Further, the heat sink 20 may be forcibly air-cooled by a cooling fan.

Here, operation of the thermoelectric module 210 may be carried out through a rapid cooling operation to cool room-temperature water to low-temperature water and a cold reserving operation to maintain the temperature of the low-temperature water.

In the case that two thermoelectric modules 210 are used, both thermoelectric modules 210 are simultaneously operated in a rapid cooling section and thereafter only one thermoelectric module 210 is operated and operation of the other thermoelectric module 210 is stopped in a cold reserving section.

In the case that operation of the thermoelectric module 210 is stopped (TEM Off) as such, a hot part of the stopped thermoelectric module 210 does not generate heat and, thus, a temperature T1 (° C.) of the condensation unit of the heat dissipating module 10 is higher than a temperature T2 (° C.) of the evaporation unit of the heat dissipating module 10.

Accordingly, in such a situation, as exemplarily shown by arrows displayed as a dotted line in FIG. 6, outdoor heat (atmospheric heat) may be introduced into the cooling container 100 through the heat dissipating module 10 and the thermoelectric module 210. That is, outdoor heat may be introduced into the cooling container 100 (the cold water tank of the water purifier) and, thus, the temperature of the cold water tank of the water purifier may be raised.

Therefore, the present invention suggests use of a loop heat pipe structure, such as heat dissipating modules. Otherwise, the present invention suggests application of a loop heat pipe structure to a heat dissipating module related to at least a thermoelectric module, which is intermittently operated according to a temperature of a cooling container. That is, as one example applied to a water purifier, a loop heat pipe structure is applied to a heat dissipating module connected to a thermoelectric module, operation of which is stopped in a cold reserving section.

Use of the above-described loop heat pipe structure has the following advantages, as compared to a general heat pipe structure.

That is, since both a vapor passage and a liquid passage are provided in the same pipe unit of the general heat pipe structure and a wick structure is provided on the entirety of the inside of the pipe unit, the general heat pipe structure has a large size and high vapor and liquid flow resistance and may thus have difficulty transferring a large amount of heat.

On the other hand, since a vapor passage and a liquid passage are separately provided in the loop heat pipe structure, the loop heat pipe structure may transfer a large amount of heat, as compared to the general heat pipe structure.

Further, in the loop heat pipe structure, since the wick structure is provided only in the evaporation unit and is not provided in the condensation unit, when operation of the related thermoelectric module is stopped, heat transfer is not carried out.

As the working fluid in the loop heat pipe structure and the working fluid in the general heat pipe structure, the same material may be used.

In the above-described cooling apparatus shown in FIG. 1, the two thermoelectric modules, i.e., the first thermoelectric module 210 and the second thermoelectric module 220, are installed, and the first heat dissipating module 300 and the second heat dissipating module 400 corresponding to the first thermoelectric module 210 and the second thermoelectric module 220 are installed.

Although the heat sinks 350 and 450 may be directly attached to the hot parts of the thermoelectric modules 210 and 220 so as to cool the hot parts of the thermoelectric modules 210 and 220, the thermoelectric modules 210 and 220 have a high heating density (of about 2.5 W/cm² or more) and the heat sinks 350 and 450 have high thermal resistance and, thus, the heat sinks 350 and 450 may not sufficiently lower the temperature of the hot parts of the thermoelectric modules 210 and 220.

Therefore, the heat dissipating modules 300 and 400 may be installed so as to improve cooling effect, as exemplarily shown in this figure.

In the cold reserving operation of the water purifier, in the case that the first thermoelectric module 210 and the second thermoelectric module 220 are simultaneously operated, the temperatures of the condensation units 320 and 420 of the heat dissipating modules 300 and 400 are higher than an outdoor temperature and, thus, outdoor heat is not introduced into the cooling container 100 through the heat dissipating modules 300 and 400, but a larger amount of electricity may be consumed, as compared to the cold reserving operation of the water purifier while only one thermoelectric module is operated.

Therefore, in the cold reserving operation of the water purifier, operation of the second thermoelectric module 220 and stoppage of the first thermoelectric module 210 may be advantageous in terms of power consumption.

FIG. 1 exemplarily illustrates the case that a loop heat pipe structure is applied to both the first heat dissipating module 300 and the second heat dissipating module 400.

Here, in the rapid cooling operation, the two thermoelectric modules 210 and 220 are simultaneously operated and, thus, both the first heat dissipating module 300 and the second heat dissipating module 400 are operated, as described above.

In the cold reserving operation, the second thermoelectric module 220 is normally operated but operation of the first thermoelectric module 210 is stopped. However, even in the case that the temperature of the condensation unit 320 of the first heat dissipating module 300 is higher than the temperature of the evaporation unit 310, outdoor heat is not introduced into the cooling container 100.

Such a case will be described in more detail. Equation 1 below states the operating condition of the loop heat pipe structure.

ΔP_{cap.}>(ΔPᵥ+ΔPₗ+ΔP_{g}) [Equation 1]

In Equation 1, ΔP_{cap.} represents a capillary force difference, ΔPᵥ represents pressure drop of the vapor pipe line, ΔPₗ represents pressure drop of the liquid pipe line and ΔP_{g} represents pressure drop due to gravity.

Here, the capillary force difference ΔP_{cap.} corresponds to a value acquired by dividing surface tension σ of the working fluid by a capillary radius rw (ΔP_{cap.}=σ/rw).

In this case, no wick structure is provided in the condensation unit 320 and capillary force becomes ‘0’. Therefore, even in the case that operation of the first thermoelectric module 210 is stopped and thus the temperature of the condensation unit 320 of the first heat dissipating module 300 is higher than the temperature of the evaporation unit 310, outdoor heat is not introduced into the cooling container 100.

Further, FIG. 4 exemplarily illustrates the case that a loop heat pipe structure is applied to the first heat dissipating module 300 and a general heat pipe structure is applied to the second heat dissipating module 400.

Here, in the rapid cooling operation, the two thermoelectric modules 210 and 220 are simultaneously operated and, thus, both the first heat dissipating module 300 and the second heat dissipating module 400 are operated, as described above.

In the cold reserving operation, the second thermoelectric module 220 is normally operated but operation of the first thermoelectric module 210 is stopped. Here, the second thermoelectric module 220 is always operated and may thus use the general heat pipe structure.

However, since the first heat dissipating module 300 has the loop heat pipe structure, even in the case that the temperature of the condensation unit 320 of the first heat dissipating module 300 is higher than the temperature of the evaporation unit 310, outdoor heat is not introduced into the cooling container 100. The first heat dissipating module 300 is the same as the first heat dissipation module 300 of FIG. 1 and a detailed description thereof will thus be omitted.

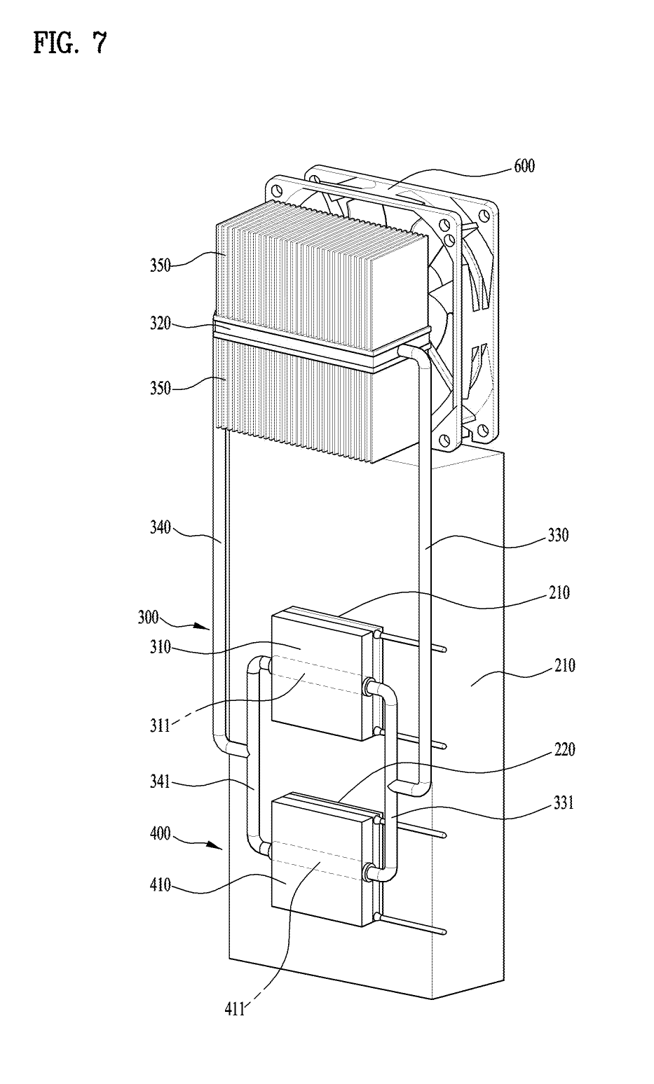

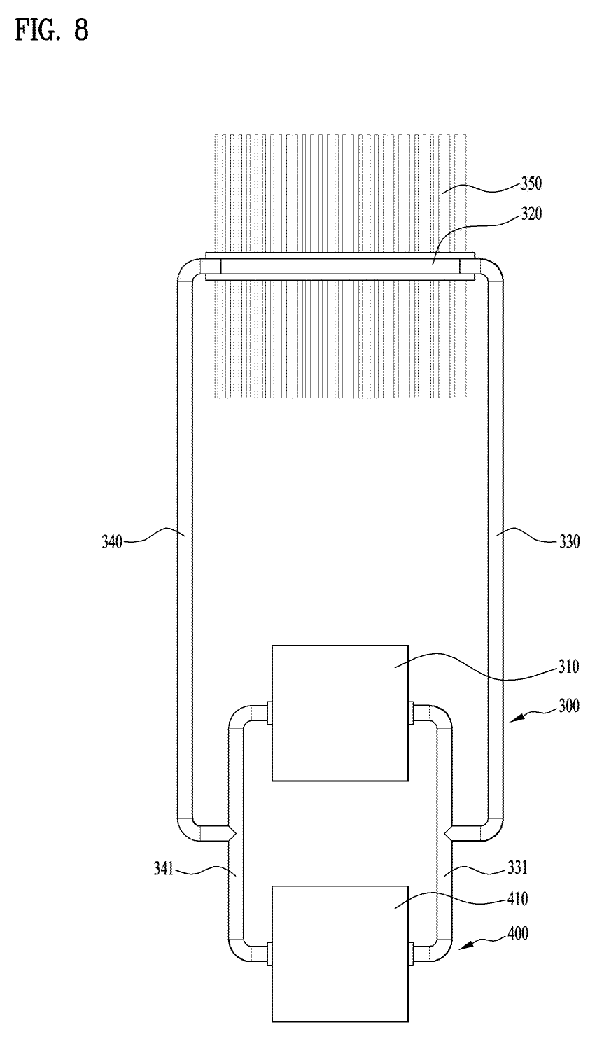

FIG. 7 is a perspective view illustrating a cooling apparatus using thermoelectric modules in accordance with another embodiment of the present invention. FIG. 8 is a schematic view illustrating the cooling apparatus shown in FIG. 7.

With reference to FIGS. 7 and 8, the cooling apparatus includes a cooling container 100, at least two thermoelectric modules 210 and 220 installed on the cooling container 100, and heat dissipating modules 300 and 400 installed so as to contact the thermoelectric modules 210 and 220.

Here, the cooling container 100 may be a part of an apparatus using cooling action using the thermoelectric modules 210 and 220. For example, the cooling container 100 may be an inner space of an apparatus using cooling action, such as a water tank (a cold water tank) of a water purifier or a refrigerating chamber of a refrigerator. Such a refrigerator may include a portable refrigerator or a refrigerator for vehicles. However, the cooling container 100 is not limited to these apparatuses and may be applied to all apparatuses which use cooling action using the thermoelectric modules 210 and 220.

The thermoelectric modules (TEM) 210 and 220 include a thermoelectric material using the thermoelectric effect.

The heat dissipating modules 300 and 400 may be elements to transmit heat, generated together with cooling action of the thermoelectric modules 210 and 220, to the outside. The heat dissipating modules 300 and 400 may be respectively installed so as to contact the thermoelectric modules 210 and 220.

The heat dissipating modules 300 and 400 may have a loop heat pipe structure. For example, one of the thermoelectric modules 210 and 220 may be intermittently operated, and the other of the thermoelectric modules 210 and 220 may be continuously operated.

Here, the heat dissipating module (hereinafter referred to as a first heat dissipating module 300) installed on the thermoelectric module which is intermittently operated may have a loop heat pipe structure, and the heat dissipating module (hereinafter referred to as a second heat dissipating module 400) installed on the thermoelectric module which is continuously operated may also have a loop heat pipe structure.

The first heat dissipating module 300 and the second heat dissipating module 400 having a loop heat pipe structure have the above-described configuration and a detailed description thereof will thus be omitted because it is considered to be unnecessary.

Here, a first evaporation unit 310 of the first heat dissipating module 300 and a second evaporation unit 410 of the second heat dissipating module 400 may be connected in parallel to a first vapor pipe line 330 and a first liquid pipe line 340 through a vapor sub-pipe line 331 and a liquid sub-pipe line 341.

According to circumstances, three or more evaporations units may be connected in parallel to the first vapor pipe line 330 and the first liquid pipe line 340 through the vapor sub-pipe line 331 and the liquid sub-pipe line 341.

Operation of such a cooling apparatus in accordance with this embodiment is the same as operation of the cooling apparatus in accordance with the former embodiment shown in FIG. 1 and a detailed description thereof will thus be omitted because it is considered to be unnecessary.

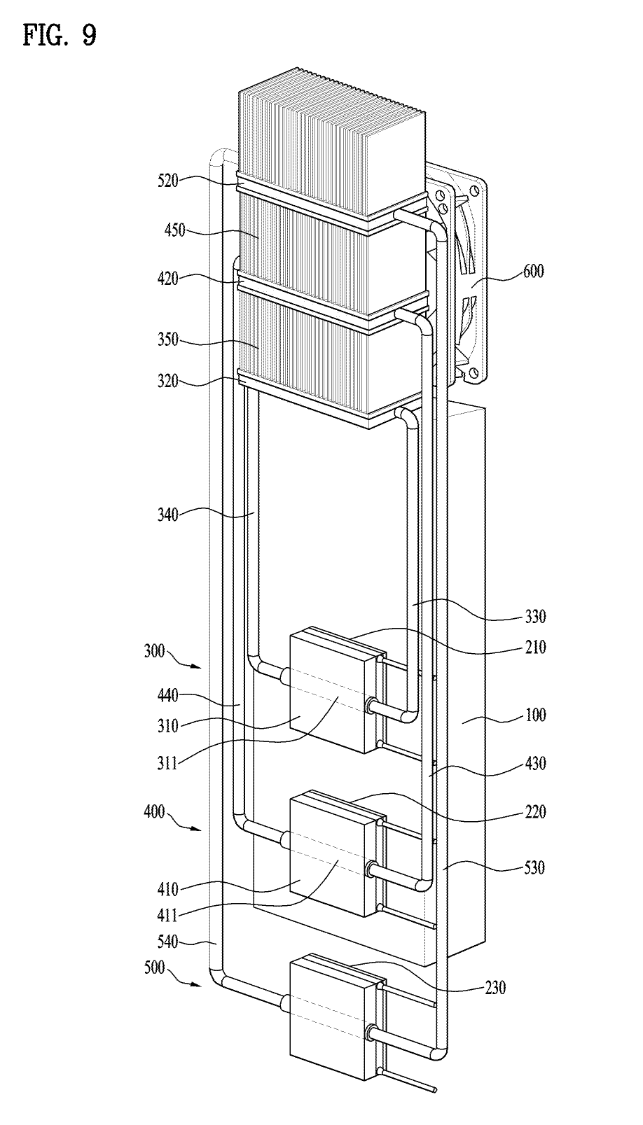

FIG. 9 is a perspective view illustrating a cooling apparatus using thermoelectric modules in accordance with yet another embodiment of the present invention.

With reference to FIG. 9, the cooling apparatus further includes a third thermoelectric module 230 and a third heat dissipating module 500 installed so as to contact the third thermoelectric module 230, in addition to the configuration shown in FIG. 1.

The present invention may be applied to such a case that three or more thermoelectric modules are installed and thus three or more heat dissipating modules are installed.

As one example, the heat dissipating module (hereinafter referred to as a first heat dissipating module 300) installed on the thermoelectric module 210 which is intermittently operated may have a loop heat pipe structure, and the heat dissipating modules (hereinafter referred to as a second heat dissipating module 400 and a third heat dissipating module 500) installed on the thermoelectric modules 220 and 230 which are continuously operated may have also a loop heat pipe structure or a heat pipe structure.

As another example, the heat dissipating modules (hereinafter referred to as the first heat dissipating module 300 and the second heat dissipating module 400) installed on the thermoelectric modules 210 and 220 which are intermittently operated may have a loop heat pipe structure, and the heat dissipating module (hereinafter referred to as the third heat dissipating module 500) installed on the thermoelectric module 230 which is continuously operated may also have a loop heat pipe structure or a heat pipe structure.

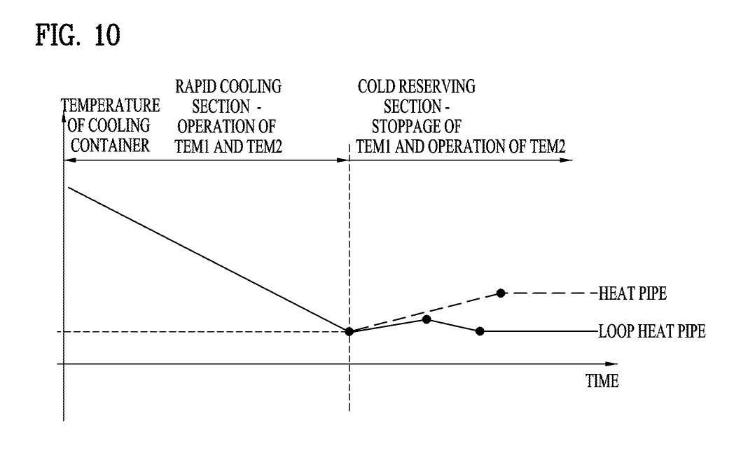

FIG. 10 is a graph representing performance of a cooling apparatus using thermoelectric modules in accordance with the present invention.

The graph of FIG. 10 illustrates cooling performance of a cooling apparatus using two thermoelectric modules (TEM1 and TEM2) 210 and 220, in which a heat dissipating module 300 having a loop heat pipe structure is applied to the first thermoelectric module (TEM1) 210, operation of which is stopped in at least a cold reserving section.

That is, in a rapid cooling section, both the two thermoelectric modules (TEM1 and TEM2) 210 and 220 are operated and, thus, two heat dissipating modules 300 and 400 are operated.

Then, in the cold reserving section, the second thermoelectric module (TEM2) 220 is operated but operation of the first thermoelectric module (TEM1) 210 is stopped.

Here, in the case that a heat dissipating module having a general heat pipe structure is applied, outdoor heat may be introduced into the cooling container and thus the temperature of the cooling container may be raised again.

However, in accordance with the present invention, in the case that the loop heat pipe structure is applied, outdoor heat is not introduced into the cooling container and thus the temperature of the cooling container may be effectively maintained.

As is apparent from the above description, the present invention provides a cooling apparatus using thermoelectric modules in which heat dissipating modules use a loop heat pipe structure.

It will be apparent to those skilled in the art that various modifications and variations can be made in the present invention without departing from the spirit or scope of the invention. Thus, it is intended that the present invention cover the modifications and variations of this invention provided they come within the scope of the appended claims and their equivalents.

What is claimed is:

1. A cooling apparatus using thermoelectric modules comprising:
a cooling container;
a first thermoelectric module contacting the cooling container at a first position; and
a first heat dissipating module installed so as to contact the first thermoelectric module,
wherein the first heat dissipating module comprises a loop heat pipe comprising:
a first evaporation unit contacting the first thermoelectric module and provided with a wick structure located therein;
a first condensation unit located at an outside of the cooling container;
a first vapor pipe line configured to interconnect one side of the first evaporation unit and one side of the first condensation unit and gas is placed in the first vapor pipe line; and
a first liquid pipe line configured to interconnect the other side of the first evaporation unit and the other side of the first condensation unit and a working fluid is placed in the first liquid pipe line.

2. The cooling apparatus according to claim 1, further comprising:
a second thermoelectric module contacting the cooling container at a second position; and
a second heat dissipating module installed so as to contact the second thermoelectric module.

3. The cooling apparatus according to claim 2, wherein the second heat dissipating module comprises a heat pipe comprising:
a pipe unit forming one closed space in which the working fluid is placed; and
a wick structure located at the entirety of an inside of the pipe unit.

4. The cooling apparatus according to claim 2, wherein the second heat dissipating module comprises a loop heat pipe comprising:
a second evaporation unit contacting the second thermoelectric module and provided with a wick structure located therein;
a second condensation unit located at the outside of the cooling container;
a second vapor pipe line configured to interconnect one side of the second evaporation unit and one side of the second condensation unit and the gas is placed in the second vapor pipe line; and
a second liquid pipe line configured to interconnect the other side of the second evaporation unit and the other side of the second condensation unit and the working fluid is placed in the second liquid pipe line.

5. The cooling apparatus according to claim 2, wherein the second heat dissipating module comprises a second evaporation unit contacting the second thermoelectric module and provided with a wick structure located therein, and
wherein the first evaporation unit and the second evaporation unit are connected in parallel to the first vapor pipe line and the first liquid pipe line.

6. The cooling apparatus according to claim 5, wherein the first evaporation unit and the second evaporation unit are connected in parallel to the first vapor pipe line and the first liquid pipe line through a vapor sub-pipe line and a liquid sub-pipe line.

7. The cooling apparatus according to claim 4, wherein at least one of the first condensation unit or the second condensation unit has a structure which is continuously bent within a designated area.

8. The cooling apparatus according to claim 2, wherein the first thermoelectric module is a thermoelectric module which is intermittently operated according to the temperature of the cooling container, and the second thermoelectric module is a thermoelectric module which is continuously operated.

9. A cooling apparatus using thermoelectric modules comprising:
a cooling container;
a first thermoelectric module contacting the cooling container at a first position;
a first heat dissipating module installed so as to contact the first thermoelectric module and having a loop heat pipe structure;
a second thermoelectric module contacting the cooling container at a second position; and
a second heat dissipating module installed so as to contact the second thermoelectric module and having one of a loop heat pipe structure and a heat pipe structure.

10. The cooling apparatus according to claim 9, wherein the first heat dissipating module comprises a loop heat pipe comprising:
a first evaporation unit contacting the first thermoelectric module and provided with a wick structure located therein;
a first condensation unit located at an outside of the cooling container;
a first vapor pipe line configured to interconnect one side of the first evaporation unit and one side of the first condensation unit and gas is placed in the first vapor pipe line; and
a first liquid pipe line configured to interconnect the other side of the first evaporation unit and the other side of the first condensation unit and a working fluid is placed in the first liquid pipe line.

11. The cooling apparatus according to claim 10, wherein the second heat dissipating module comprises a heat pipe comprising:
a pipe unit forming one closed space in which the working fluid is placed; and
a wick structure located at the entirety of an inside of the pipe unit.

12. The cooling apparatus according to claim 10, wherein the second heat dissipating module comprises a loop heat pipe comprising:
a second evaporation unit contacting the second thermoelectric module and provided with a wick structure located therein;
a second condensation unit located at the outside of the cooling container;
a second vapor pipe line configured to interconnect one side of the second evaporation unit and one side of the second condensation unit and the gas is placed in the second vapor pipe line; and
a second liquid pipe line configured to interconnect the other side of the second evaporation unit and the other side of the second condensation unit and the working fluid is placed in the second liquid pipe line.

13. The cooling apparatus according to claim 12, wherein the second heat dissipating module comprises a second evaporation unit contacting the second thermoelectric module and provided with a wick structure located therein, and
wherein the first evaporation unit and the second evaporation unit are connected in parallel to the first vapor pipe line and the first liquid pipe line through a vapor sub-pipe line and a liquid sub-pipe line.

14. The cooling apparatus according to claim 12, wherein at least one of the first condensation unit or the second condensation unit has a structure which is continuously bent within a designated area.

15. The cooling apparatus according to claim 10, wherein the first thermoelectric module is a thermoelectric module which is intermittently operated according to the temperature of the cooling container, and the second thermoelectric module is a thermoelectric module which is continuously operated.

16. A cooling apparatus using thermoelectric modules comprising:
a cooling container; and
at least two thermoelectric modules installed on the cooling container, and heat dissipating modules installed so as to contact the at least two thermoelectric modules,
wherein, among the heat dissipating modules, the first heat dissipating module installed on the thermoelectric module, which is intermittently operated according to the temperature of the cooling container, has a loop heat pipe structure, and the second heat dissipating module installed on the thermoelectric module, which is continuously operated, has one of a loop heat pipe structure and a heat pipe structure.

17. The cooling apparatus according to claim 16, wherein the heat dissipating module having the loop heat pipe structure comprises:
an evaporation unit contacting the thermoelectric module and provided with a wick structure located therein;
a condensation unit located at an outside of the cooling container;
a vapor pipe line configured to interconnect one side of the evaporation unit and one side of the condensation unit such that gas is placed in the vapor pipe line; and
a liquid pipe line configured to interconnect the other side of the evaporation unit and the other side of the condensation unit such that a working fluid is placed in the liquid pipe line.

18. The cooling apparatus according to claim 17, wherein the condensation unit has a structure which is continuously bent within a designated area.

19. The cooling apparatus according to claim 16, wherein the heat dissipating module having the heat pipe structure comprises a heat pipe comprising:
a pipe unit forming one closed space in which the working fluid is placed; and
a wick structure located at the entirety of an inside of the pipe unit.

20. The cooling apparatus according to claim 16, wherein, when the second heat dissipating module has the loop heat pipe structure, the first heat dissipating module and the second heat dissipating module are connected in parallel.
